(19) United States
(12) Patent Application Publication
(10) Pub. No.: US 2019/0334113 A1
(43) Pub. Date: Oct. 31, 2019

(54) OLED DISPLAY DEVICE

(71) Applicant: Wuhan China Star Optoelectronics Technology Co., Ltd., Wuhan City HB (CN)

(72) Inventors: Xueyun Li, Wuhan City (CN); Yuejun Tang, Wuhan City (CN)

(21) Appl. No.: 16/096,297

(22) PCT Filed: Sep. 13, 2018
(86) PCT No.: PCT/CN2018/105583

§ 371 Date: Oct. 25, 2018

(30) Foreign Application Priority Data
Apr. 27, 2018 (CN) 201810394064.2

(51) Int. Cl. H01L 51/52; H01L 51/50

(52) U.S. Cl. CPC H01L 51/5246; H01L 51/5012

(57) ABSTRACT

The invention provides an OLED display device, comprising: a lower package layer, at least two adjacent OLED display units disposed on the lower package layer, and an upper package layer disposed on the at least two adjacent OLED display units; each OLED display unit comprising a substrate disposed on the lower package layer and a light-emitting layer disposed on the substrate. The at least two adjacent OLED display units are integrally package by the lower and the upper package layers. Therefore, a packaging structure for each OLED display unit is not necessary, so that the light-emitting layer in the adjacent OLED display unit of the present invention achieves seamless docking, which reduces the segmentation sense of the OLED display device, and reduces the gap between adjacent OLED display units and the light-emitting layers as well as improves the display quality of the OLED display device.

### BACKGROUND OF THE INVENTION

### 1. Field of the Invention

The present invention relates to the field of display and, in particular, to the field of an OLED display device.

### 2. The Related Arts

The organic light-emitting diode (OLED) display, also known as organic electroluminescent display, is a new type of flat panel display device. Because of the advantages of self-emission, low driving voltage, high luminous efficiency, short response time, high definition and contrast, near 180° viewing angle, and wide operating temperature range, ability to realize flexible display and large-area full-color display, the OLED display device is recognized by the industry as the most promising display device.

The OLED element generally comprises: a substrate, an anode disposed on the substrate, a hole injection layer disposed on the anode, a hole transport layer disposed on the hole injection layer, a light-emitting layer disposed on the hole transport layer, an electron transport layer disposed on the light-emitting layer, an electron injection layer disposed on the electron transport layer, and a cathode disposed on the electron injection layer. The light-emitting principle behind the OLED element is that the semiconductor material and the organic light-emitting material, driven by the electric field, cause light emission through carrier injection and recombination. Specifically, an OLED element generally employs an indium tin oxide (ITO) electrode and a metal electrode as the anode and the cathode, respectively. When driven by a certain voltage, electrons and holes are injected from the cathode and the anode into the electron transport layer and the hole transport layer, respectively. The electrons and holes migrate to the light-emitting layer through the electron transport layer and the hole transport layer, respectively, and meet at the light-emitting layer to form excitons and excite the light-emitting molecules, which emit visible light through radiation relaxation.

The known large-scale OLED display devices are difficult to manufacture. Therefore, two or more smaller OLED display devices are usually spliced together to form a large OLED display device. However, the splicing gaps at the splicing seams of a plurality of OLED display devices are difficult to completely eliminate in prior art, and the displayed image will suffer a screen segmentation. To prevent moisture and oxygen from entering the light-emitting area of the OLED display device causing reduced the lifespan of the OLED device, the OLED display device must be packaged, and a sufficient package width is required at the frame of the OLED display device to block moisture and oxygen from entering. Therefore, the gaps of the splicing OLED display device may become more pronounced because of the larger width of the package border.

### SUMMARY OF THE INVENTION

The primary object of the present invention is to provide an OLED display device, providing low segmentation sensation and small splicing gaps.

To achieve the above objects, the present invention provides an OLED display device, which comprises: a lower package layer, at least two adjacent OLED display units disposed on the lower package layer, and an upper package layer disposed on the at least two adjacent OLED display units;

each OLED display unit comprising a substrate disposed on the lower package layer and a light-emitting layer disposed on the substrate.

Preferably, each OLED display unit further comprises a bonding terminal provided on the substrate and at a side facing away from the adjacent OLED display unit and the light-emitting layer, a plurality of data lines extending vertically and electrically connected to the bonding terminal and the light-emitting layer, and a plurality of scan lines extending horizontally and electrically connected to the bonding terminals and the light-emitting layer.

Preferably, each OLED display unit further comprises a blocking layer disposed on the substrate and covering a region of the light-emitting layer other than the side facing the adjacent OLED display unit.

Preferably, each OLED display unit further comprises a desiccant disposed between the substrate and the upper package layer and on a side of the light-emitting layer facing away from the adjacent OLED display unit.

Preferably, the OLED display device further comprises a sealant disposed between the lower package layer and the upper package layer and located at periphery of each OLED display unit.

Preferably, the OLED display device further comprises a sealant disposed simultaneously between the lower package layer and the upper package layer and between the substrate of each OLED display unit and the upper package layer, and located at periphery of the light-emitting layer of each OLED display unit.

Preferably, the OLED display device further comprises a sealant disposed between the substrate of each OLED display unit and the upper package layer and located between the light-emitting layer and the bonding terminals of each OLED display unit.

Preferably, the OLED display device further comprises an adhesive layer disposed between the lower package layer and the substrate of each OLED display unit.

Preferably, the at least two adjacent OLED display units have the same or different thickness.

Preferably, the lower package layer is made of a transparent material or an opaque material, and the upper package layer is made of a transparent material or an opaque material different from the lower package layer.

The present invention provides the following advantages: the OLED display device of the present invention comprises: which comprises: a lower package layer, at least two adjacent OLED display units disposed on the lower package layer, and an upper package layer disposed on the at least two adjacent OLED display units; each OLED display unit comprising a substrate disposed on the lower package layer and a light-emitting layer disposed on the substrate. The at least two adjacent OLED display units are integrally package by the lower and the upper package layers. Therefore, a packaging structure for each OLED display unit is not necessary, so that the light-emitting layer in the adjacent OLED display unit of the present invention achieves seamless docking, which reduces the segmentation sense of the OLED display device, and reduces the gap between adjacent OLED display units and the light-emitting layers as well as improves the display quality of the OLED display device.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort.

FIG. 1 is a top cross-sectional view showing the OLED display device according to the first exemplary embodiment of the present invention.

FIG. 2 is a cross-sectional view along A-A in FIG. 1.

FIG. 3 is a top cross-sectional view showing the OLED display device according to the second exemplary embodiment of the present invention.

FIG. 4 is a cross-sectional view along B-B in FIG. 3.

FIG. 5 is a top cross-sectional view showing the OLED display device according to the third exemplary embodiment of the present invention.

FIG. 6 is a cross-sectional view along C-C in FIG. 5.

### DETAILED DESCRIPTION OF THE PREFERRED EMBODIMENTS

To further explain the technical means and effect of the present invention, the following refers to embodiments and drawings for detailed description. Apparently, the described embodiments are merely some embodiments of the present invention, instead of all embodiments. All other embodiments based on embodiments in the present invention and obtained by those skilled in the art without departing from the creative work of the present invention are within the scope of the present invention.

The terms “comprising” and “having” and any variations thereof appearing in the specification, claims, and drawings of the present application are intended to cover non-exclusive inclusion. For example, a process, method, system, product, or device that includes a series of steps or units is not limited to the listed steps or units, but optionally also includes steps or units not listed, or alternatively, other steps or units inherent to these processes, methods, products or equipment. In addition, the terms “first”, “second” and “third” are used to distinguish different objects and not intended to describe a particular order.

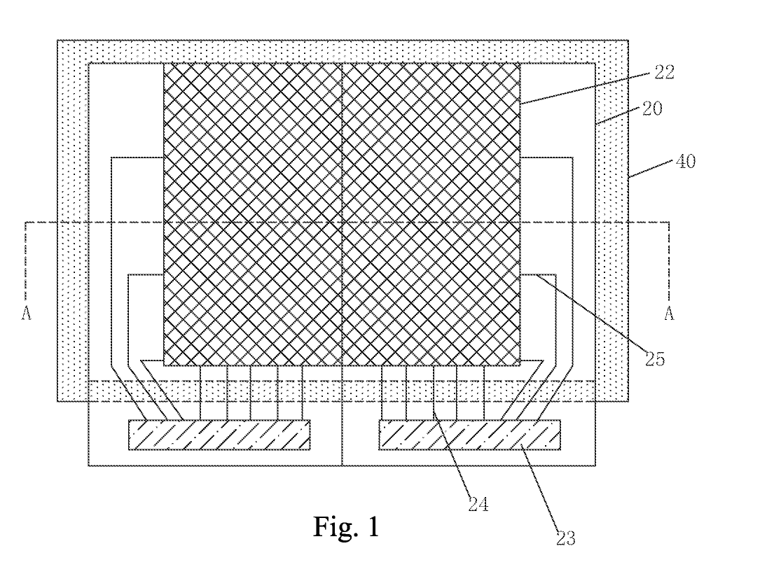

Refer to FIGS. 1-6. The OLED display device of the present invention comprises: a lower package layer 10, at least two adjacent OLED display units 20 disposed on the lower package layer 10, and an upper package layer 30 disposed on the at least two adjacent OLED display units 20;

each OLED display unit 20 comprising a substrate 21 disposed on the lower package layer 10 and a light-emitting layer 22 disposed on the substrate 21.

It should be noted that, in the present invention, the at least two adjacent OLED display units 20 are integrally package by the lower and the upper package layers 10, 30. Therefore, a packaging structure for each OLED display unit 20 is not necessary and the problem of larger package width at the splicing in the prior is not applicable to the present invention. As such, the light-emitting layer 22 in the adjacent OLED display unit 20 of the present invention achieves seamless docking, which reduces the segmentation sense of the OLED display device, and reduces the gap between adjacent OLED display units 20 and the light-emitting layers 22 as well as improves the display quality of the OLED display device.

Specifically, the thicknesses of the at least two adjacent OLED display units 20 may be the same or different. When the thicknesses are the same, all the OLED display units 20 are disposed on the same plane, which is favorable for improving the overall package result; when the thicknesses are different, the lower surfaces of the substrates 21 of all the OLED display units 20 can be disposed on the same plane, or all the upper surfaces of the light-emitting layers 22 of the OLED display units 20 are disposed on the same plane to improve the overall package result.

Specifically, the substrate 21 is made of one of the following materials: glass, metal, polyimide (PI) and polycarbonate (PC).

Specifically, each OLED display unit 20 further comprises a bonding terminal 23 disposed on the substrate 21 and at a side facing away from the adjacent OLED display unit 20 and the light emitting layer 22, a plurality of data lines 24 extending vertically and electrically connected to the bonding terminal 23 and the light-emitting layer 22, and a plurality of scan lines 25 extending horizontally and electrically connected to the bonding terminals 23 and the light-emitting layer 22. As such, the routings for each OLED display unit 20 are far from the side facing the adjacent OLED display unit 20, and the gap between the light-emitting layers 22 of the adjacent OLED display units 20 is further reduced. Clearly, the alignment of each OLED display unit 20 comprises not only the above data line 24 and the scan line 25, but also other routings, such as, a power signal line for supplying an electrical signal to the pixel electrode or the anode, which is not illustrated in the present invention here. In addition, each OLED display unit 20 may further comprises a gate driving circuit and a signal line connected to the gate driving circuit. In a preferred embodiment, the gate driving circuit can also be disposed away from the side facing the adjacent OLED display unit 20 to avoid increasing the gap between the light-emitting layers 22 of the adjacent OLED display units 20.

Specifically, the bonding terminals 23 are further disposed with pads for bonding with a flexible circuit board (FPC) and an integrated circuit (IC) for electrical connection to provide electrical signals to the data line 24 and the scan line 25. The light-emitting layer 22 comprises a plurality of sub-pixels arranged in an array, and the data lines 24 and the scan lines 25 are used to transmit electrical signals to a plurality of sub-pixels.

Specifically, each OLED display unit 20 further comprises a blocking layer 26 disposed on the substrate 21 and covering a region of the light-emitting layer 22 other than the side facing the adjacent OLED display unit 20 to improve the blocking ability of the OLED display device against moisture without increasing the gap between the light-emitting layers 22 of adjacent OLED display units 20.

Specifically, the lower package layer 10 is made of a transparent material or an opaque material, and the upper package layer 30 is made of a transparent material or an opaque material different from the lower package layer 10 to realize the top-emitting OLED display device as well as bottom-emitting OLED display device.

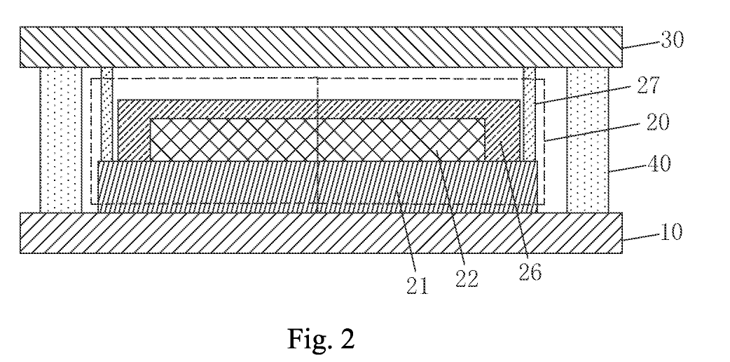

Refer to FIG. 1 and FIG. 2. FIG. 1 is a top cross-sectional view showing the OLED display device according to the first exemplary embodiment of the present invention. FIG. 2 is a cross-sectional view along A-A in FIG. 1. Optionally, the OLED display device further comprises a sealant 40 disposed between the lower package layer 10 and the upper package layer 30 and located at periphery of each OLED display unit 20. Moreover, the OLED display device further comprises an adhesive layer disposed between the lower package layer 10 and the substrate 21 of each OLED display unit 20, which is not shown here.

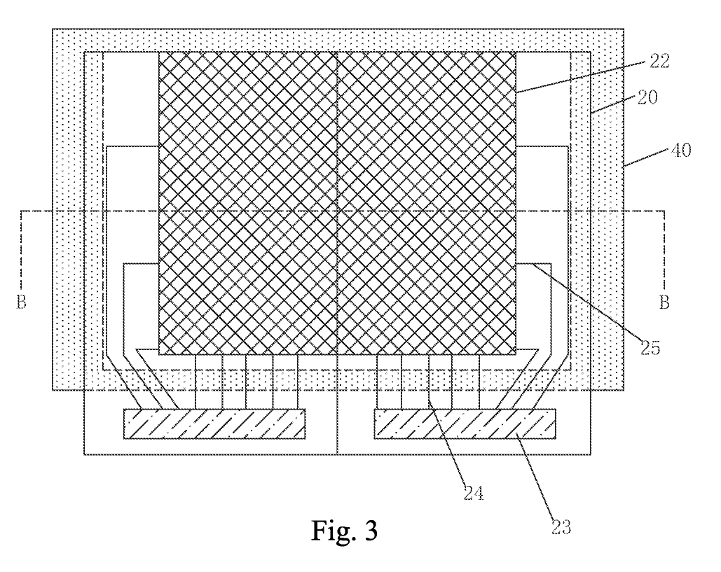

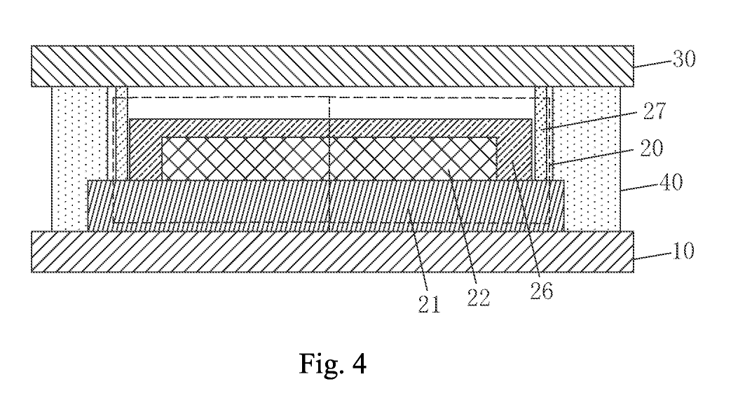

Refer to FIG. 3 and FIG. 4. FIG. 3 is a top cross-sectional view showing the OLED display device according to the second exemplary embodiment of the present invention. FIG. 4 is a cross-sectional view along B-B in FIG. 3. Optionally, the OLED display device further comprises a sealant 40 disposed simultaneously between the lower package layer 10 and the upper package layer 30 and between the substrate 21 of each OLED display unit 20 and the upper package layer 30, and located at periphery of the light-emitting layer 22 of each OLED display unit 20 to improve the total package result and the moisture-blocking ability. Moreover, the OLED display device further comprises an adhesive layer disposed between the lower package layer 10 and the substrate 21 of each OLED display unit 20, which is not shown here.

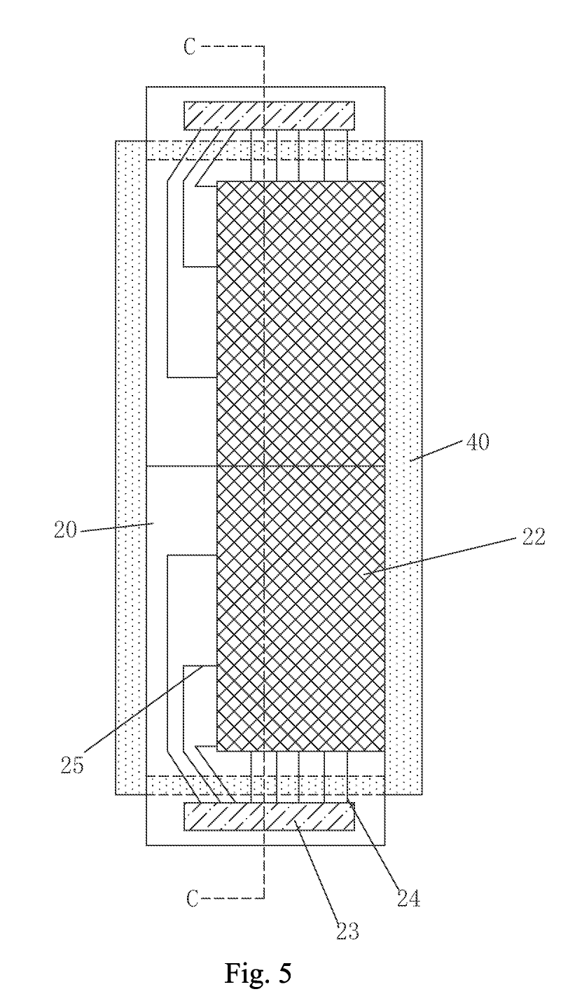

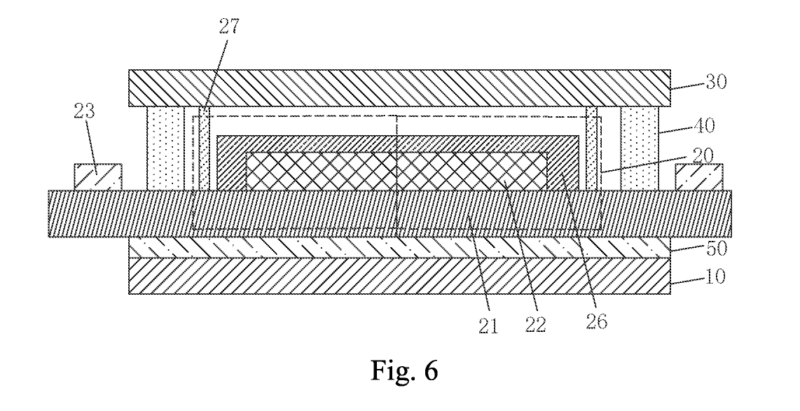

Refer to FIG. 5 and FIG. 6. FIG. 5 is a top cross-sectional view showing the OLED display device according to the third exemplary embodiment of the present invention. FIG. 6 is a cross-sectional view along C-C in FIG. 5. Optionally, the OLED display device further comprises a sealant 40 disposed between the substrate 21 of each OLED display unit 20 and the upper package layer 30 and located between the light-emitting layer 22 and the bonding terminals 23 of each OLED display unit 20 so that the bonding terminals 23 of each OLED display unit 20 are exposed outside the package of the OLED display device to better connect to external flexible circuit board and the integrated circuit.

Moreover, the OLED display device further comprises an adhesive layer 50 disposed between the lower package layer 10 and the substrate 21 of each OLED display unit 20. Since the bonding terminals 23 of each OLED display unit 20 are away from the side facing the adjacent OLED display unit 20, the adhesion layer 50 has an extremely wide width and is possible to effectively prevent moisture from passing through the adhesion layer 50, entering the side facing the adjacent OLED display unit 20 side and then entering the light-emitting layer 22 again, which improves the lifespan of the OLED display device.

In summary, The OLED display device of the present invention comprises: a lower package layer, at least two adjacent OLED display units disposed on the lower package layer, and an upper package layer disposed on the at least two adjacent OLED display units; each OLED display unit comprising a substrate disposed on the lower package layer and a light-emitting layer disposed on the substrate. The at least two adjacent OLED display units are integrally package by the lower and the upper package layers. Therefore, a packaging structure for each OLED display unit is not necessary, so that the light-emitting layer in the adjacent OLED display unit of the present invention achieves seamless docking, which reduces the segmentation sense of the OLED display device, and reduces the gap between adjacent OLED display units and the light-emitting layers as well as improves the display quality of the OLED display device.

It should be noted that each of the embodiments in this specification is described in a progressive manner, each of which is primarily described in connection with other embodiments with emphasis on the difference parts, and the same or similar parts may be seen from each other. For the device embodiment, since it is substantially similar to the method embodiment, the description is relatively simple and the relevant description may be described in part of the method embodiment.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. An organic light-emitting diode (OLED) display device, comprising: a lower package layer, at least two adjacent OLED display units disposed on the lower package layer, and an upper package layer disposed on the at least two adjacent OLED display units;
each OLED display unit comprising a substrate disposed on the lower package layer and a light-emitting layer disposed on the substrate.

2. The OLED display device as claimed in claim 1, wherein each OLED display unit further comprises a bonding terminal provided on the substrate and at a side facing away from the adjacent OLED display unit and the light-emitting layer, a plurality of data lines extending vertically and electrically connected to the bonding terminal and the light-emitting layer, and a plurality of scan lines extending horizontally and electrically connected to the bonding terminals and the light-emitting layer.

3. The OLED display device as claimed in claim 1, wherein each OLED display unit further comprises a blocking layer disposed on the substrate and covering a region of the light-emitting layer other than the side facing the adjacent OLED display unit.

4. The OLED display device as claimed in claim 1, wherein each OLED display unit further comprises a desiccant disposed between the substrate and the upper package layer and on a side of the light-emitting layer facing away from the adjacent OLED display unit.

5. The OLED display device as claimed in claim 1, further comprising a sealant disposed between the lower package layer and the upper package layer and located at periphery of each OLED display unit.

6. The OLED display device as claimed in claim 1, further comprising a sealant disposed simultaneously between the lower package layer and the upper package layer and between the substrate of each OLED display unit and the upper package layer, and located at periphery of the light-emitting layer of each OLED display unit.

7. The OLED display device as claimed in claim 2, further comprising a sealant disposed between the substrate of each OLED display unit and the upper package layer and located between the light-emitting layer and the bonding terminals of each OLED display unit.

8. The OLED display device as claimed in claim 7, further comprising an adhesive layer disposed between the lower package layer and the substrate of each OLED display unit.

9. The OLED display device as claimed in claim 1, wherein the at least two adjacent OLED display units have the same or different thickness.

10. The OLED display device as claimed in claim 1, wherein the lower package layer is made of a transparent material or an opaque material, and the upper package layer is made of a transparent material or an opaque material different from the lower package layer.
